(19) United States
(12) Patent Application Publication
(10) Pub. No.: US 2024/0290921 A1
(43) Pub. Date: Aug. 29, 2024

(54) LIGHT-EMITTING DIODE DISPLAY APPARATUS

(71) Applicant: LG Display Co., Ltd., Seoul (KR)

(72) Inventors: Seongyong Cho, Paju-si (KR); Wook Jeon, Paju-si (KR)

(73) Assignee: LG Display Co., Ltd., Seoul (KR)

(21) Appl. No.: 18/413,339

(22) Filed: Jan. 16, 2024

(30) Foreign Application Priority Data
Feb. 28, 2023 (KR) 10-2023-0027029

(51) Int. Cl. H01L 33/60; H01L 25/16

(52) U.S. Cl. CPC H01L 33/60; H01L 25/167

(57) ABSTRACT

A light-emitting diode display apparatus may include a substrate, a light-emitting diode provided on the substrate, and a scattering pattern provided on the light emitting diode, wherein the scattering pattern is disposed such that a part of light generated from the light-emitting diode, which is not emitted toward a front surface of the light-emitting diode display apparatus, passes through the scattering pattern and does not overlap the light-emitting.

### CROSS-REFERENCE TO RELATED APPLICATIONS

This application claims the benefit of and the priority from the Korean Patent Application No. 10-2023-0027029, filed on Feb. 28, 2023, which is hereby incorporated by reference as if fully set forth herein.

### BACKGROUND

### Technical Field

The present disclosure relates to a display apparatus, and more particularly, to a light-emitting diode display apparatus that includes a light-emitting diode.

### Description of the Related Art

A display apparatus has been widely used as a display screen for a laptop computer, a tablet computer, a smart phone, a portable display device and a portable information device in addition to a display screen of a televisions or a monitor. A liquid crystal display apparatus and an organic light-emitting display apparatus display an image by using a thin film transistor as switching elements. Since the liquid crystal display apparatus has a backlight unit, there is limitation in design, and luminance and response speed may be deteriorated. Since the organic light-emitting display apparatus includes an organic material, it is vulnerable to moisture, whereby reliability and lifespan may be deteriorated.

Recently, research and development of a light-emitting diode display apparatus using a micro light-emitting diode are ongoing, and this light-emitting diode display apparatus has been spotlighted as a next-generation display apparatus because of its high definition and high reliability.

The light-emitting diode display apparatus may have a problem in that a stain may occur in a panel due to a rapid luminance difference between a front surface and a side of the panel. Also, a problem may occur in that asymmetry is generated in luminance of left and right directional angles due to a P/N electrode structure of a light-emitting diode. In addition, a problem may occur in that non-uniformity of a viewing angle according to a position of the light-emitting diode is increased due to transfer tolerance of the light-emitting diode. In particular, the light-emitting diode display apparatus may have a luminance distribution of an ‘M’ shape having maximum luminance at a viewing angle greater than 0°, similarly to luminance distribution per viewing angle of the light generated from the light-emitting diode, and thus may have an inefficient luminance distribution due to low luminance on a front surface of display apparatus at a viewing angle of 0°.

### SUMMARY

The present disclosure has been made in view of the above problems and it is an object of the present disclosure to provide a light-emitting diode display apparatus in which light efficiency is improved.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a light-emitting diode display apparatus comprising a substrate, a light-emitting diode provided on the substrate, and a scattering pattern provided on the light emitting diode, wherein the scattering pattern is disposed such that a part of light generated from the light-emitting diode which is not emitted toward a front surface of the light-emitting diode display apparatus passes through the scattering pattern and does not overlap the light-emitting diode.

In accordance with another aspect of the present disclosure, the above and other objects can be accomplished by the provision of a light-emitting diode display apparatus comprising: a substrate in which a plurality of pixels are disposed; first and second light-emitting diodes respectively disposed in two of the plurality of pixels on the substrate; a bank disposed in an area, which does not overlap the first and second light-emitting diodes, on the substrate; a lens or a reflective structure disposed to overlap each of the first and second light-emitting diodes; and a scattering pattern disposed on the lens or the reflective structure, wherein a partial area of the scattering pattern overlaps the bank.

It is to be understood that both the foregoing general description and the following detailed description of the present disclosure are by way of example and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a schematic view illustrating a display apparatus according to one embodiment of the present disclosure;

FIG. 2A is a partial cross-sectional view illustrating a display apparatus according to one embodiment of the present disclosure;

FIG. 2B is a perspective view illustrating a tiling display apparatus according to one embodiment of the present disclosure;

FIG. 3 is an enlarged plan view illustrating a display apparatus according to one embodiment of the present disclosure;

FIG. 4A is a partial cross-sectional view illustrating a display apparatus according to one embodiment of the present disclosure;

FIG. 4B is a partial a cross-sectional view illustrating a first light-emitting diode according to one embodiment of the present disclosure;

FIGS. 5A and 5D are a plan view and a cross-sectional view illustrating a first light-emitting diode according to one embodiment of the present disclosure;

FIGS. 5B and 5E are a plan view and a cross-sectional view illustrating a second light-emitting diode according to one embodiment of the present disclosure;

FIGS. 5C and 5F are a plan view and a cross-sectional view illustrating a third light-emitting diode according to one embodiment of the present disclosure;

FIG. 6A is a partial cross-sectional view illustrating a display apparatus according to a comparative embodiment of the present disclosure;

FIG. 6B is a partial cross-sectional view illustrating a position relationship in a display apparatus according to one embodiment of the present disclosure;

FIGS. 7A and 7B are a graph and a table illustrating a luminance change of a display apparatus according to one embodiment of the present disclosure;

FIGS. 8A and 8B are enlarged plan views illustrating a display apparatus according to another embodiment of the present disclosure;

FIGS. 9A and 9B are partial cross-sectional views illustrating a process of forming a scattering pattern;

FIGS. 10A and 10B are partial cross-sectional views illustrating a display apparatus according to another embodiment of the present disclosure; and

FIGS. 11A to 11D are graphs and tables illustrating a luminance change of a display apparatus according to another embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The same reference numerals will refer to the same elements throughout the specification.

An area and a thickness of each element disclosed in the drawings are shown for convenience of description, and the present disclosure is not limited to the shown details.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship. Hereinafter, the present disclosure will be described in detail with reference to the accompanying drawings.

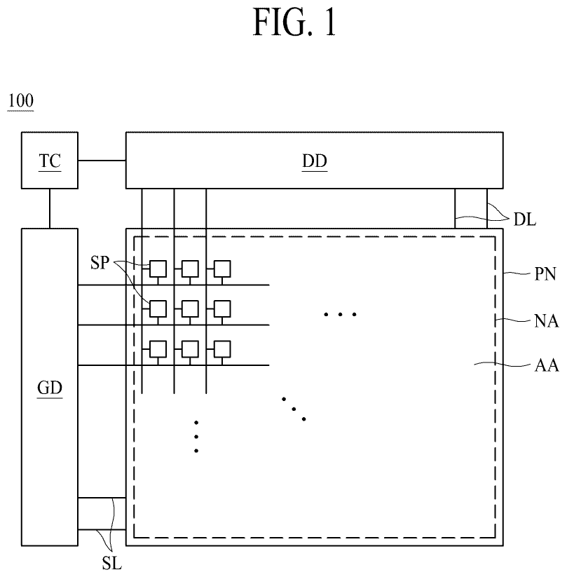

FIG. 1 is a schematic view illustrating a display apparatus according to one embodiment of the present disclosure. For convenience of description, a display panel PN, a gate driver GD, a data driver DD, and a timing controller TC among various elements of the display apparatus 100 are shown in FIG. 1.

With reference to FIG. 1, the display apparatus 100 includes a display panel PN including a plurality of subpixels SP, a gate driver GD and a data driver DD, which supply various signals to the display panel PN, and a timing controller TC for controlling the gate driver GD and the data driver DD.

The gate driver GD supplies a plurality of scan signals to a plurality of scan lines SL in accordance with a plurality of gate control signals provided from the timing controller TC. In FIG. 1, one gate driver GD is disposed to be spaced apart from one side of the display panel PN, but the number and arrangement of the gate drivers GD are not limited thereto.

The data driver DD converts image data input from the timing controller TC into a data voltage by using a reference gamma voltage in accordance with a plurality of data control signals provided from the timing controller TC. The data driver DD may supply the converted data voltage to a plurality of data lines DL.

The timing controller TC aligns externally input image data and supplies the aligned image data to the data driver DD. The timing controller TC may generate a gate control signal and a data control signal by using externally input synchronization signals, for example, a dot clock signal, a data enable signal and a horizontal/vertical synchronization signal. In addition, the timing controller TC may control the gate driver GD and the data driver DD by supplying the gate control signal and the data control signal to the gate driver GD and the data driver DD, respectively.

The display panel PN is an element for displaying an image to a user, and a display area AA for displaying an image and a non-display area NA surrounding the display area AA may be defined in the display panel PN.

A plurality of subpixels SP constituting a plurality of pixels PX and a circuit for driving the plurality of subpixels SP may be disposed in the display area AA. The plurality of subpixels SP are minimum units constituting the display area AA, and ‘n’ number of subpixels SP may constitute one pixel PX. A light-emitting diode LED and a thin film transistor TFT for driving the light-emitting diode LED may be disposed in each of the plurality of subpixels SP. For example, when the display panel PN is an inorganic light-emitting display panel PN, a light-emitting element may be a light-emitting diode LED or a micro LED, but is not limited thereto. Various modifications may be made in the light-emitting element included in the display panel PN depending on the type of the display panel PN.

A plurality of signal lines for transferring various signals to the plurality of subpixels SP are disposed in the display area AA. For example, the plurality of signal lines may include a plurality of data lines DL for supplying a data voltage to each of the plurality of subpixels SP, and a plurality of scan lines SL for supplying a gate voltage to each of the plurality of subpixels SP. The plurality of scan lines SL may be extended in the display area AA in one direction and thus connected to the plurality of subpixels SP, and the plurality of data lines DL may be extended in the display area AA in a direction different from the one direction and thus connected to the plurality of subpixels SP. In addition, a first power line VDD, a second power line VSS, and the like may be further disposed in the display area AA, but the present disclosure is not limited thereto.

The non-display area NA is an area in which an image is not displayed, and may be formed to surround the display area AA. A link line and a pad electrode, which are for transferring a signal to the subpixel SP of the display area AA, and a driving IC (i.e., integrated circuit) such as a gate driver IC and a data driver IC may be disposed in the non-display area NA. The non-display area NA may be positioned on a rear surface of the display panel PN, that is, a surface having no subpixel SP or may be omitted, and is not limited to what is shown in the drawing.

The driver such as the gate driver GD, the data driver DD and the timing controller TC may be connected to the display panel PN in various ways. For example, the gate driver GD may be packaged in the non-display area NA in a Gate In Panel (GIP) mode, or may be packaged between the plurality of subpixels SP in the display area AA in a Gate In Active area (GIA) mode. For example, the data driver DD and the timing controller TC may be formed in a separate flexible film and a printed circuit board, and may be electrically connected to the display panel PN in a way of bonding the flexible film and the printed circuit board to the pad electrode formed in the non-display area NA of the display panel PN. If the gate driver GD is packaged in the GIP mode and the data driver DD and the timing controller TC transfer a signal to the display panel PN through the pad electrode of the non-display area NA, it is necessary to make sure of an area of the non-display area NA for disposing the gate driver GD and the pad electrode, and a bezel may be increased.

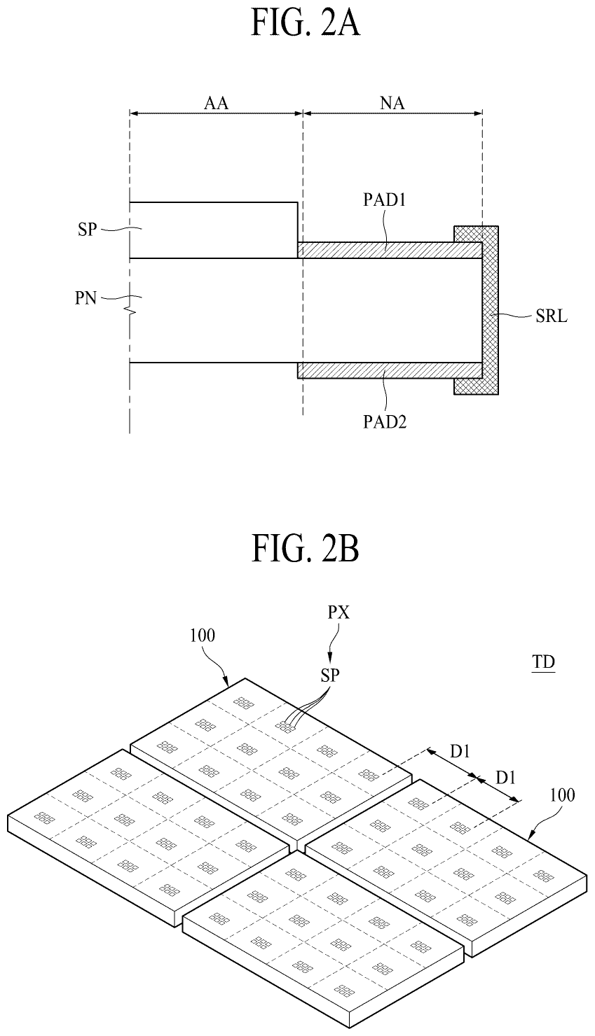

Unlike the above example, if the gate driver GD is packaged inside the display area AA in the GIA mode and a side line SRL connecting a signal line on a front surface of the display panel PN with a pad electrode on a rear surface of the display panel PN is formed to bond the flexible film and the printed circuit board to the rear surface of the display panel PN, the non-display area NA may be reduced in a minimum range on the front surface of the display panel PN. That is, when the gate driver GD, the data driver DD, and the timing controller TC are connected to the display panel PN in the above-described manner, a zero bezel in which a bezel does not exist substantially may be implemented. This will be described in more detail with reference to FIGS. 2A and 2B.

FIG. 2A is a partial cross-sectional view illustrating a display apparatus according to one embodiment of the present disclosure.

A plurality of pad electrodes for transferring various signals to the plurality of subpixels SP are disposed in the non-display area NA of the display panel PN. For example, a first pad electrode PAD1 for transferring a signal to the plurality of subpixels SP is disposed in the non-display area NA on the front surface of the display panel PN, and a second pad electrode PAD2 electrically connected to a driving component such as a flexible film and a printed circuit board is disposed in the non-display area NA on the rear surface of the display panel PN.

In this case, various signal lines connected to the plurality of subpixels SP, for example, scan lines SL or data lines DL, may be extended from the display area AA to the non-display area NA and thus electrically connected to the first pad electrode PAD1.

A side line SRL is disposed along a side of the display panel PN. The side line SRL may electrically connect the first pad electrode PAD1 on the front surface of the display panel PN with the second pad electrode PAD2 on the rear surface of the display panel PN. Therefore, the signal from the driving component of the rear surface of the display panel PN may be transferred to the plurality of subpixels SP through the second pad electrode PAD2, the side line SRL and the first pad electrode PAD1. Therefore, a signal transfer path from the front surface to the side and rear surface of the display panel PN may be formed so that an area of the non-display area NA of the display panel PN may be minimized.

FIG. 2B is a perspective view illustrating a tiling display apparatus according to one embodiment of the present disclosure.

With reference to FIG. 2B, a plurality of display apparatuses 100 may be connected so that a tiling display apparatus TD having a large screen may be implemented. As shown in FIG. 2A, when the tiling display apparatus TD is implemented using the display apparatuses 100 having a minimized bezel, a seam area, which is an area between two adjacent display apparatuses 100 in which an image is not displayed, may be reduced, whereby display quality may be improved.

For example, the plurality of subpixels SP may constitute one pixel PX, and a distance D1 between an outermost pixel PX of one display apparatus 100 and an outermost pixel PX of another display apparatus 100 adjacent thereto may be implemented to be the same as a distance D1 between the two adjacent pixels PX in one display apparatus 100. Therefore, the seam area of the tiling display apparatus TD may be reduced so that the distance between the adjacent pixels PX is constant between the two adjacent display apparatuses 100, whereby the tiling display apparatus TD having no sense of difference in the seam area may be implemented.

However, FIGS. 2A and 2B are exemplary, and the display apparatus 100 according to one embodiment of the present disclosure may be the display apparatus 100 in which a bezel is present, but is not limited thereto.

Hereinafter, X-axis represents a direction parallel with a gate line, and Y-axis represents a direction parallel with a data line.

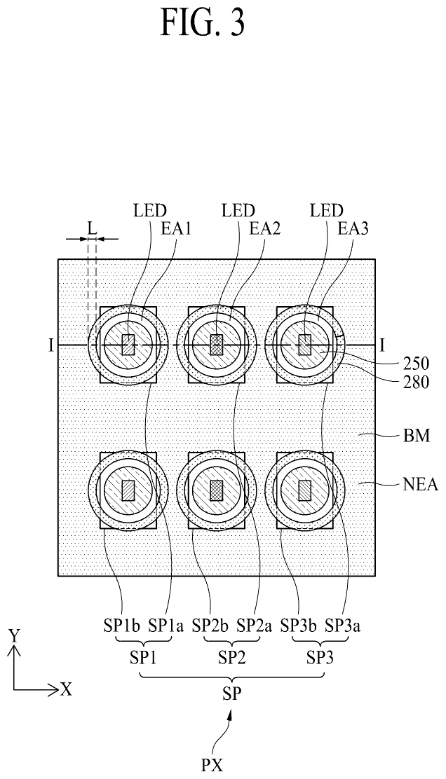

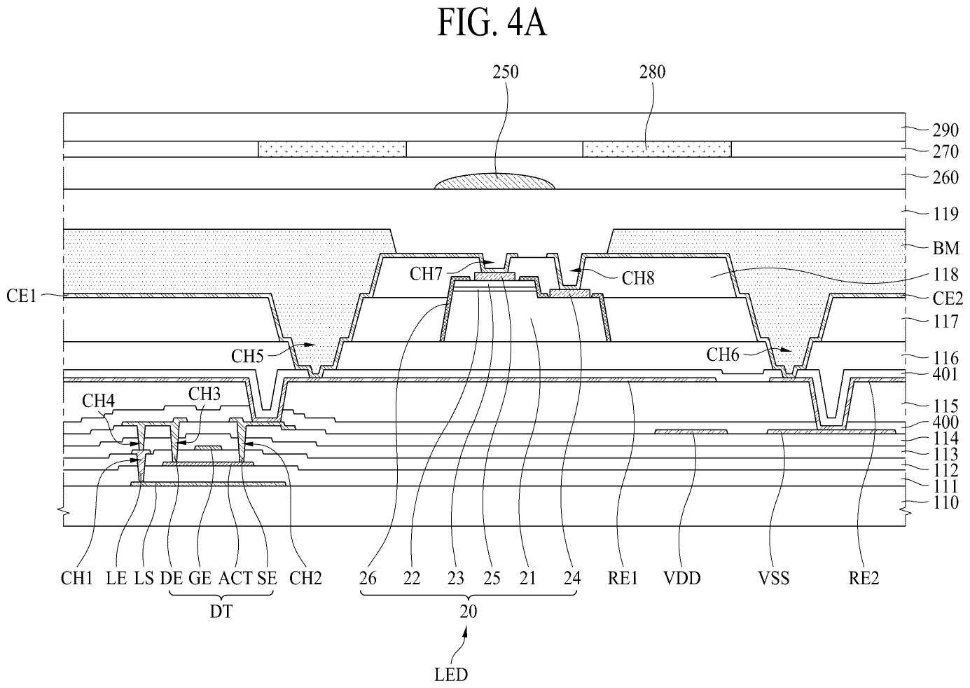

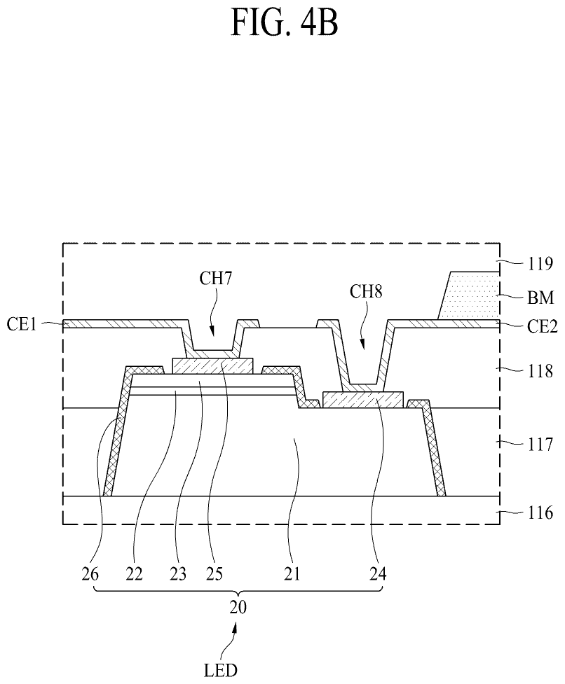

FIG. 3 is an enlarged plan view illustrating a display apparatus according to one embodiment of the present disclosure. FIG. 4A is a partial cross-sectional view illustrating a display apparatus according to one embodiment of the present disclosure.

With reference to FIG. 3, the display panel PN includes a plurality of pixels PX, each of which includes a plurality of subpixels SP. Each of the plurality of subpixels SP may include a light-emitting diode LED and a pixel circuit to independently emit light. For example, the first subpixel SP1 may be a red subpixel, the second subpixel SP2 may be a green subpixel and the third subpixel SP3 may be a blue subpixel, but the present disclosure is not limited thereto.

One pixel PX may include a plurality of subpixels SP including a first subpixel SP1, a second subpixel SP2, and a third subpixel SP3. For example, one pixel PX may include two first subpixels SP1, two second subpixels SP2, and two third subpixels SP3. The first subpixel SP1 includes a (1-1)th subpixel SP1a and a (1-2)th subpixel SP1b, the second subpixel SP2 includes a (2-1)th subpixel SP2a and a (2-2)th subpixel SP2b, and the third subpixel SP3 includes a (3-1)th subpixel SP3a and a (3-2)th subpixel SP3b. The (1-1)th subpixel SP1a, the (2-1)th subpixel SP2a and the (3-1)th subpixel SP3a may be disposed in the same row, and the (1-2)th subpixel SP1b, the (2-2)th subpixel SP2b and the (3-2)th subpixel SP3b may be disposed in the same row.

With reference to FIG. 4A, a substrate 110, a buffer layer 111, a gate insulating layer 112, a first interlayer insulating layer 113, a second interlayer insulating layer 114, a third interlayer insulating layer 400, a first planarization layer 115, a fourth interlayer insulating layer 401, an adhesive layer 116, a second planarization layer 117, a third planarization layer 118, a driving transistor DT, a light-emitting diode LED, a plurality of reflective electrodes RE1 and RE2, a plurality of first connection electrodes CE1, a second connection electrode CE2, a light-shielding layer LS and an auxiliary electrode LE are disposed in each of the plurality of subpixels SP of the display panel PN of the display apparatus 100 according to one embodiment of the present disclosure.

The substrate 110 is an element for supporting various elements included in the display apparatus 100, and may be made of an insulating material. For example, the substrate 110 may be made of glass or resin. In addition, the substrate 110 may include a polymer or plastic, or may be formed of a material having flexibility. The display apparatus according to one embodiment of the present disclosure may be configured in a top emission mode in which emitted light is emitted toward an upper portion. Therefore, the substrate 110 may be made of an opaque material as well as a transparent material.

The light-shielding layer LS is disposed in each of the plurality of subpixels SP on the substrate 110. The light-shielding layer LS shields light incident to the active layer ACT of the driving transistor DT from a lower portion of the substrate 110. The light incident to the active layer ACT of the driving transistor DT may be shielded by the light-shielding layer LS, so that a leakage current may be reduced.

The buffer layer 111 is disposed on the substrate 110 and the light-shielding layer LS. The buffer layer 111 may reduce permeation of moisture or impurities through the substrate 110. The buffer layer 111 may be formed of, for example, a single layer or multi-layer of silicon oxide (SiOx) or silicon nitride (SiNx), but is not limited thereto. However, the buffer layer 111 may be omitted depending on the type of the substrate 110 or the type of the driving transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon or polysilicon, but is not limited thereto.

The gate insulating layer 112 is disposed on the active layer ACT. The gate insulating layer 112 is an insulating layer for insulating the active layer ACT and the gate electrode GE from each other, and may be formed of a single layer or multi-layer of silicon oxide (SiOx) or silicon nitride (SiNx), but is not limited thereto.

The gate electrode GE is disposed on the gate insulation layer 112. The gate electrode GE may include a conductive material, for example, copper (Cu), aluminum (Al), molybdenum (Mo), nickel (Ni), titanium (Ti), chromium (Cr) or their alloy, but is not limited thereto.

The first interlayer insulating layer 113 and the second interlayer insulating layer 114 are disposed on the gate electrode GE. A contact hole is formed in the first interlayer insulating layer 113 and the second interlayer insulating layer 114 so that each of the source electrode SE and the drain electrode DE is connected to the active layer ACT. The first interlayer insulating layer 113 and the second interlayer insulating layer 114 are insulating layers for protecting elements below the first interlayer insulating layer 113 and the second interlayer insulating layer 114, and may be formed of a single layer or multi-layer of silicon oxide (SiOx) or silicon nitride (SiNx), but is not limited thereto.

The source electrode SE and the drain electrode DE, which are electrically connected to the active layer ACT, are disposed on the second interlayer insulating layer 114. The source electrode SE and the drain electrode DE may be made of a conductive material, for example, copper (Cu), aluminum (Al), molybdenum (Mo), nickel (Ni), titanium (Ti), chromium (Cr) or their alloy, but is not limited thereto.

In the present disclosure, although the first interlayer insulating layer 113 and the second interlayer insulating layer 114, that is, a plurality of insulating layers are disposed between the gate electrode GE and the source and drain electrodes SE and DE, only one insulating layer may be disposed between the gate electrode GE and the source and drain electrodes SE and DE, but is not limited thereto.

When the plurality of insulating layers such as the first interlayer insulating layer 113 and the second interlayer insulating layer 114 are disposed between the gate electrode GE and the source and drain electrodes SE and DE as shown in the drawing, an electrode may be additionally formed between the first interlayer insulating layer 113 and the second interlayer insulating layer 114, and the additional electrode may form a capacitor together with other elements disposed below the first interlayer insulating layer 113 or above the second interlayer insulating layer 114.

The auxiliary electrode LE is disposed on the gate insulation layer 112. The auxiliary electrode LE is an electrode for electrically connecting the light-shielding layer LS below the buffer layer 111 to any one of the source electrode SE and the drain electrode DE on the second interlayer insulation layer 114. For example, since the light-shielding layer LS is electrically connected to any one of the source electrode SE or the drain electrode DE through the auxiliary electrode LE and does not operate as a floating gate, threshold voltage variation of the driving transistor DT, which is generated by the floated light-shielding layer LS, may be minimized. In the drawing, the light-shielding layer LS is shown as being connected to the drain electrode DE through a first contact hole CH1 passing through the buffer layer 111 and the gate insulating layer 112 and a fourth contact hole CH4 passing through the first interlayer insulating layer 113 and the second interlayer insulating layer 114, but the light-shielding layer LS may be connected to the source electrode SE, and is not limited thereto.

The source electrode SE, the drain electrode DE, the first power line VDD and the second power line VSS are disposed on the second interlayer insulation layer 114. In the drawing, the source electrode SE is shown as being connected to the active layer ACT through a second contact hole CH2 passing through the gate insulating layer 112, the first interlayer insulating layer 113 and the second interlayer insulating layer 114, and the drain electrode DE is shown as being connected to the active layer ACT through a third contact hole CH3 passing through the gate insulating layer 112, the first interlayer insulating layer 113 and the second interlayer insulating layer 114, but is not limited thereto. The first power line VDD and the second power line VSS may be electrically connected to the light-emitting diode LED and the driving transistor DT to allow the light-emitting diode LED to emit light. The first power line VDD and the second power line VSS may be made of a conductive material, for example, copper (Cu), aluminum (Al), molybdenum (Mo), nickel (Ni), titanium (Ti), chromium (Cr) or their alloy, but is not limited thereto.

The third interlayer insulating layer 400 may be disposed on the driving transistor DT, the first power line VDD, and the second power line VSS. The third interlayer insulating layer 400 is an insulating layer for protecting the element thereunder, and may be formed of a single layer or multi-layer of silicon oxide (SiOx) or silicon nitride (SiNx), but is not limited thereto.

The first planarization layer 115 is disposed on the third interlayer insulating layer 400. The first planarization layer 115 may planarize an upper portion of the substrate 110 on which the driving transistor DT is disposed. The first planarization layer 115 may be formed of a single layer or multi-layer, and may be made of, for example, a photoresist or an acryl-based organic material, but is not limited thereto.

The plurality of reflective electrodes RE1 and RE2 spaced apart from each other are disposed on the first planarization layer 115. The plurality of reflective electrodes RE1 and RE2 electrically connect the light-emitting diode LED to the second power line VSS and the driving transistor DT, and at the same time may function as reflectors for reflecting light emitted from the light-emitting diode LED to an upper portion of the light-emitting diode LED. The plurality of reflective electrodes RE1 and RE2 are formed of a conductive material having excellent reflective characteristics, and may reflect the light emitted from the light-emitting diode LED toward the upper portion of the light-emitting diode LED.

The plurality of reflective electrodes RE1 and RE2 include a first reflective electrode RE1 and a second reflective electrode RE2. The first reflective electrode RE1 may electrically connect the driving transistor DT with the light-emitting diode LED. The first reflective electrode RE1 may be connected to the source electrode SE or the drain electrode DE of the driving transistor DT through a contact hole formed in the first planarization layer 115. The first reflective electrode RE1 may be electrically connected to a first electrode and a first semiconductor layer of the light-emitting diode LED through the first connection electrode CE1 that will be described later.

The second reflective electrode RE2 may electrically connect the second power line VSS to the light-emitting diode LED. The second reflective electrode RE2 may be connected to the second power line VSS through a contact hole formed in the first planarization layer 115, and may be electrically connected to a second electrode and a second semiconductor layer of the light-emitting diode LED through the second connection electrode CE2 that will be described later.

The fourth interlayer insulating layer 401 may be disposed on the plurality of reflective electrodes RE1 and RE2. The fourth interlayer insulating layer 401 is an insulating layer for protecting the element below the fourth interlayer insulating layer 401, and may be formed of a single layer or multi-layer of silicon oxide (SiOx) or silicon nitride (SiNx), but is not limited thereto.

The adhesive layer 116 is disposed on the fourth interlayer insulating layer 401. The adhesive layer 116 may be coated on an entire surface of the substrate 110 to fix the light-emitting diode LED disposed on the adhesive layer 116. The adhesive layer 116 may be selected from any one of, for example, an adhesive polymer, an epoxy resin, a UV resin, a polyimide-based resin, an acrylate-based resin, a urethane-based resin, or polydimethylsiloxane (PDMS), but is not limited thereto.

The plurality of light-emitting diodes LED are disposed in each of the plurality of subpixels SP on the adhesive layer 116. The plurality of light-emitting diodes LED may include light-emitting diodes LED for emitting red light, green light, blue light and the like as elements for emitting light by a current, and may implement light of various colors including white by a combination thereof. For example, the plurality of light-emitting diodes LED may be light-emitting diodes LED or micro LEDs, but are not limited thereto.

With reference to FIGS. 3, 4A, and 5A to 5F together, the plurality of light-emitting diodes LED include a lateral light-emitting diode 20. The lateral light-emitting diode 20 may be disposed in each of the subpixels SP. The lateral light-emitting diodes 20 disposed in the subpixels SP may emit red light, green light, and blue light, respectively. For example, the lateral light-emitting diode 20 disposed in the first subpixel SP1 may emit red light, the lateral light-emitting diode 20 disposed in the second subpixel SP2 may emit green light, and the lateral light-emitting diode 20 disposed in the third subpixel SP3 may emit blue light.

With reference to FIGS. 4A and 4B, the lateral light-emitting diode 20 includes an n-type semiconductor layer 21, a light-emitting layer 22, a p-type semiconductor layer 23, an n-type electrode 24, a p-type electrode 25, and an encapsulation layer 26.

The n-type semiconductor layer 21 is disposed on the adhesive layer 116, and the p-type semiconductor layer 23 is disposed on the n-type semiconductor layer 21. The n-type semiconductor layer 21 and the p-type semiconductor layer 23 may be formed by doping n-type impurities and p-type impurities in a specific material. For example, each of the n-type semiconductor layer 21 and the p-type semiconductor layer 23 may be a layer doped with n-type and p-type impurities in a material such as gallium nitride (GaN), indium aluminum phosphide (InAlP) and gallium arsenide (GaAs). The p-type impurities may be magnesium, zinc (Zn), beryllium (Be) and the like, and the n-type impurities may be silicon (Si), germanium, tin (Sn) and the like, but the present disclosure is not limited thereto.

The light-emitting layer 22 is disposed between the n-type semiconductor layer 21 and the p-type semiconductor layer 23. The light-emitting layer 22 may emit light by receiving holes and electrons from the n-type semiconductor layer 21 and the p-type semiconductor layer 23. The light-emitting layer 22 may have a single-layered structure or a multi-quantum well (MQW) structure, and may include, for example, indium gallium nitride (InGaN) or gallium nitride (GaN), but is not limited thereto.

The n-type electrode 24 is disposed on the n-type semiconductor layer 21. The n-type electrode 24 is an electrode for electrically connecting the second power line VSS with the n-type semiconductor layer 21. The n-type electrode 24 may be disposed on an upper surface of the n-type semiconductor layer 21, which is exposed from the light-emitting layer 22 and the p-type semiconductor layer 23. For example, the n-type electrode 24 is disposed along the circumference of the upper surface of the n-type semiconductor layer 21, and may have a circular planar shape. The n-type electrode 24 may be made of a conductive material, for example, a transparent conductive material such as Indium Tin Oxide (ITO) or Indium Zinc Oxide (IZO) or an opaque conductive material such as titanium (Ti), gold (Au), silver (Ag), copper (Cu) or their alloy, but is not limited thereto.

The p-type electrode 25 is disposed on the p-type semiconductor layer 23. The p-type electrode 25 may be disposed on the upper surface of the p-type semiconductor layer 23. The p-type electrode 25 is an electrode for electrically connecting the driving transistor DT with the p-type semiconductor layer 23. The p-type electrode 25 may be made of a conductive material, for example, a transparent conductive material such as Indium Tin Oxide (ITO) or Indium Zinc Oxide (IZO) or an opaque conductive material such as titanium (Ti), gold (Au), silver (Ag), copper (Cu) or their alloy, but is not limited thereto.

Next, the encapsulation layer 26 surrounding the n-type semiconductor layer 21, the light-emitting layer 22, the p-type semiconductor layer 23, the n-type electrode 24 and the p-type electrode 25 is disposed. The encapsulation layer 26 may be made of an insulating material to protect the n-type semiconductor layer 21, the light-emitting layer 22 and the p-type semiconductor layer 23. An eighth contact hole CH8 for exposing the n-type electrode 24 and a seventh contact hole CH7 for exposing the p-type electrode 25 is formed in the encapsulation layer 26, so that the first connection electrode CE1 and the second connection electrode CE2 may be connected to the p-type electrode 25 and the n-type electrode 24, respectively.

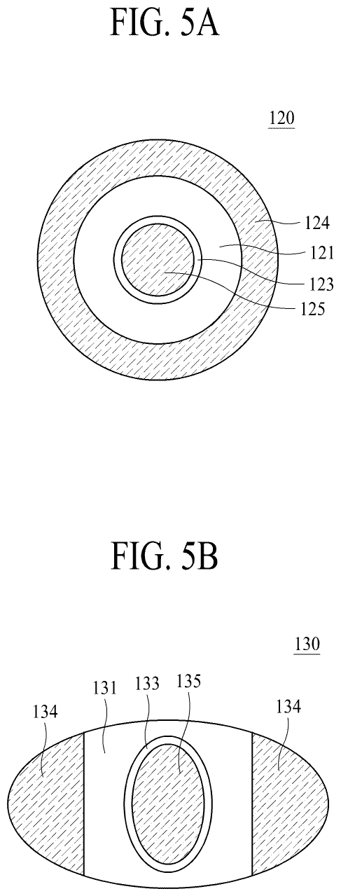

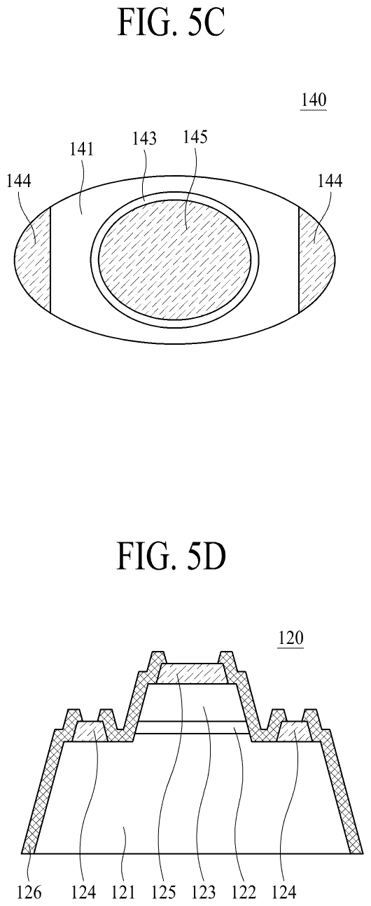

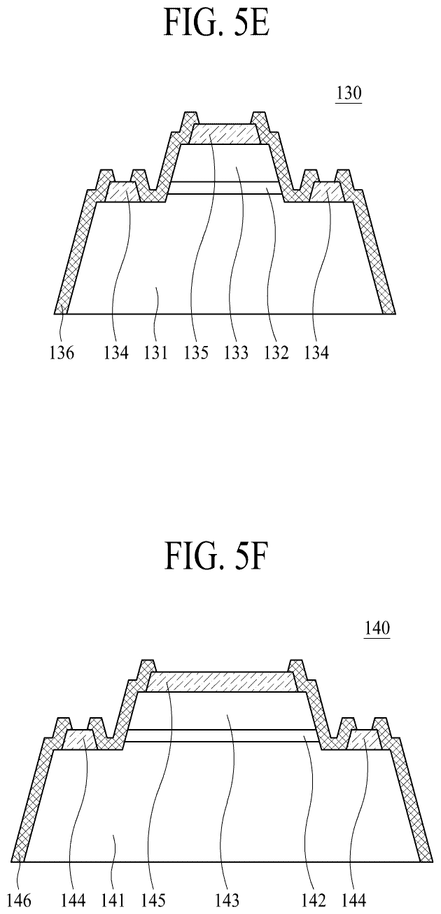

Also, the light-emitting diode LED may be formed of a light-emitting diode having a structure different from that of the lateral light-emitting diode 20. FIGS. 5a to 5e illustrate another embodiment of the light-emitting diode LED.

With reference to FIGS. 5A and 5D, in the same manner as the lateral light-emitting diode 20, the first light-emitting diode 120 includes an n-type semiconductor layer 121, a light-emitting layer 122, a p-type semiconductor layer 123, an n-type electrode 124, a p-type electrode 125 and an encapsulation layer 126, and description of the same elements as those of the lateral light-emitting diode 20 will be omitted.

With reference to FIGS. 5A and 5D, a planar shape of each of the n-type semiconductor layer 121, the light-emitting layer 122, the p-type semiconductor layer 123, the n-type electrode 124 and the p-type electrode 125 of the first light-emitting diode 120 may have a circular shape. The n-type electrode 124 may be disposed along the circumference of the n-type semiconductor layer 121 and thus may be formed as a circular electrode of a closed loop shape. The p-type electrode 125 may have a shape corresponding to an upper surface of the p-type semiconductor layer 123.

FIGS. 5B and 5E are a plan view and a cross-sectional view illustrating a second light-emitting diode 130 according to one embodiment of the present disclosure.

With reference to FIGS. 5B and 5E, in the same manner as the first light-emitting diode 120, the second light-emitting diode 130 includes an n-type semiconductor layer 131, a light-emitting layer 132, a p-type semiconductor layer 133, an n-type electrode 134, a p-type electrode 135 and an encapsulation layer 136, and description of the same elements as those of the first light-emitting diode 120 will be omitted.

Unlike the first light-emitting diode 120, a planar shape of the n-type electrode 134 of the second light-emitting diode 130 may have an oval shape. That is, the n-type electrode 134 may be disposed to be adjacent to both ends of an upper surface of the n-type semiconductor layer 131 in a long axis direction of the upper surface of the n-type semiconductor layer 131.

In addition, a planar shape of the n-type semiconductor layer 131, the p-type semiconductor layer 133 and the p-type electrode 135 of the second light-emitting diode 130 may also have an oval shape. In this case, a long axis direction of the n-type semiconductor layer 131 may be different from that of the p-type semiconductor layer 133. For example, when the n-type semiconductor layer 131 has an oval shape having a long axis in a horizontal direction, the p-type semiconductor layer 133 may have an oval shape having a long axis in a vertical direction. The n-type electrode 134 may be disposed at each of both ends of the n-type semiconductor layer 131 in the long axis direction of the upper surface of the n-type semiconductor layer 131. Therefore, the plurality of n-type electrodes 134 disposed at both ends of the n-type semiconductor layer 131 each may have a semi-circular shape. Finally, the p-type electrode 135 may have an oval shape in the same manner as the upper surface of the p-type semiconductor layer 133.

FIGS. 5C and 5F are a plan view and a cross-sectional view illustrating a third light-emitting diode 140 according to one embodiment of the present disclosure.

With reference to FIGS. 5C and 5F, in the same manner the first light-emitting diode 120, the third light-emitting diode 140 includes an n-type semiconductor layer 141, a light-emitting layer 142, a p-type semiconductor layer 143, an n-type electrode 144, a p-type electrode 145, and an encapsulation layer 146, and description of the same elements as those of the first light-emitting diode 120 will be omitted.

Unlike the first light-emitting diode 120, a planar shape of the n-type electrode 144 of the third light-emitting diode 140 may have an oval shape. That is, the n-type electrode 144 may be disposed to be adjacent to both ends of an upper surface of the n-type semiconductor layer 141 in a long axis direction of an upper surface of the n-type semiconductor layer 141.

In addition, a planar shape of each of the n-type semiconductor layer 141, the p-type semiconductor layer 143 and the p-type electrode 145 of the third light-emitting diode 140 may also have an oval shape. Unlike the second light-emitting diode 130, the long axis direction of the n-type semiconductor layer 141 and a long axis direction of the p-type semiconductor layer 143 may be the same as each other in the third light-emitting diode 140. The n-type electrode 144 may be disposed at each of both ends of the n-type semiconductor layer 141 in the long axis direction of the upper surface of the n-type semiconductor layer 141, and may be formed in a semi-circular shape. In addition, the p-type electrode 145 may have an oval shape in the same manner as the upper surface of the p-type semiconductor layer 143. The light-emitting diodes LED respectively formed in the first to third subpixels SP1 to SP3 may have their respective shapes different from one another. That is, the plurality of light-emitting diodes LED respectively include an n-type semiconductor layer, a light-emitting layer, a p-type semiconductor layer, an n-type electrode, a p-type electrode and an encapsulation layer in common, but some elements may have their respective shapes different from each other.

In the display apparatus 100 according to one embodiment of the present disclosure, the light-emitting diodes LED respectively formed in the first to third subpixels SP1 to SP3 have their respective shapes different from one another, so that the plurality of light-emitting diodes LED may be distinguished. However, the shapes of the plurality of light-emitting diodes LED are exemplary, and the present disclosure is not limited thereto. For example, the light-emitting diodes respectively formed in the first to third subpixels SP1 to SP3 may have the same shape.

With reference back to FIG. 4A, the second planarization layer 117 and the third planarization layer 118 are disposed on the plurality of light-emitting diodes LED. The second planarization layer 117 and the third planarization layer 118 may be disposed to cover the plurality of light-emitting diodes LED, thereby fixing and protecting the plurality of light-emitting diodes LED. The second planarization layer 117 and the third planarization layer 118 may be formed of a single layer or multi-layer, and may be made of, for example, a photoresist or an acryl-based organic material, but is not limited thereto. Although it has been described herein that the second planarization layer 117 and the third planarization layer 118 are disposed to cover the plurality of light-emitting diodes LED, the planarization layer covering the plurality of light-emitting diodes LED may be formed of a single layer, but is not limited thereto. In addition, the third planarization layer 118 may be positioned only in an area adjacent to the light-emitting diode LED.

After the third planarization layer 118 is deposited, a plurality of first connection electrodes CE1 and a plurality of second connection electrodes CE2 may be formed.

The first connection electrode CE1 is an electrode that is disposed in each of the plurality of subpixels SP to electrically connect the light-emitting diode LED with the driving transistor DT. The first connection electrode CE1 may be connected to the first reflective electrode RE1 through a fifth contact hole CH5 formed in the third planarization layer 118, the second planarization layer 117 and the adhesive layer 116. Therefore, the first connection electrode CE1 may be electrically connected to any one of the source electrode SE and the drain electrode DE of the driving transistor DT through the first reflective electrode RE1. The first connection electrode CE1 may be connected to an p-type electrode of each of the plurality of light-emitting diodes LED through the seventh contact hole CH7 formed in the third planarization layer 118. Therefore, the first connection electrode CE1 may electrically connect the driving transistor DT to the p-type electrode and the p-type semiconductor layer of the plurality of light-emitting diodes LED.

The second connection electrode CE2 is an electrode for electrically connecting the light-emitting diode LED with the second power line VSS. The second connection electrode CE2 may be connected to the second reflective electrode RE2 through the sixth contact hole CH6 formed in the third planarization layer 118, the second planarization layer 117 and the adhesive layer 116. Therefore, the second connection electrode CE2 may be electrically connected to the second power line VSS through the second reflective electrode RE2. The second connection electrode CE2 may be connected to a n-type electrode of each of the plurality of light-emitting diodes LED through the eighth contact hole CH8 formed in the third planarization layer 118. Therefore, the second connection electrode CE2 may electrically connect the second power line VSS to the n-type electrode and the n-type semiconductor layer of the plurality of light-emitting diodes LED.

Meanwhile, the first connection electrode CE1 connecting the driving transistor DT disposed in each of the plurality of subpixels SP with the light-emitting diode LED may be individually disposed in each of the plurality of subpixels SP. The second connection electrodes CE2 that are respectively disposed in the plurality of subpixels SP to connect the second power line VSS to the light-emitting diode LED may be connected to each other. That is, since a power voltage of the second power line VSS is commonly applied to all of the plurality of light-emitting diodes LED of the plurality of subpixels SP, one second connection electrode CE2 may be disposed in all of the plurality of subpixels SP.

A bank BM may be formed on the first connection electrode CE1 and the second connection electrode CE2. The bank BM may be provided on the third planarization layer 118 to cover at least a portion of the first connection electrode CE1 and at least a portion of the second connection electrode CE2. The bank BM may be provided to fill the fifth contact hole CH5 on the first connection electrode CE1 provided in the fifth contact hole CH5. In addition, the bank BM may be provided to fill the sixth contact hole CH6 on the second connection electrode CE2 provided in the sixth contact hole CH6.

With reference to FIG. 3, the bank BM may define emission areas EA1, EA2 and EA3 of the subpixels SP1, SP2 and SP3. The bank BM may include an opening area corresponding to the emission areas EA1, EA2 and EA3 through which light emitted from the light-emitting diode LED is emitted to the outside. The light emitted from the light-emitting diode LED provided in each of the subpixels SP1, SP2 and SP3 may be emitted to the outside in the opening area of the bank BM. Therefore, the emission areas EA1, EA2 and EA3 of the subpixels SP1, SP2 and SP3 may correspond to an area in which the bank BM is not formed.

The bank BM may be formed of an organic layer such as acryl resin, epoxy resin, phenolic resin, polyamide resin and polyimide resin, and may include a black material for absorbing light. Therefore, the light emitted from the light-emitting diode LED provided in each of the subpixels SP1, SP2 and SP3 may be absorbed in an area, in which the bank BM is formed, whereby the light may not be emitted to the outside. Therefore, the area in which the bank BM is formed may correspond to a non-emission area NEA. The bank BM may prevent the light emitted from the light-emitting diode LED from moving to the adjacent subpixels SP1, SP2 and SP3, thereby preventing color mixture from occurring among the subpixels SP1, SP2 and SP3.

A fourth planarization layer 119 may be provided on the bank BM and the first and second connection electrodes CE1 and CE2. The fourth planarization layer 119 may be provided to cover an upper surface of the bank BM and a portion of the first and second connection electrodes CE1 and CE2 exposed without being covered by the bank BM. The fourth planarization layer 119 may provide a flat surface on the bank BM.

The fourth planarization layer 119 may be formed of an organic layer such as acryl resin, epoxy resin, phenolic resin, polyamide resin and polyimide resin. The fourth planarization layer 119 may have a first refractive index.

A lens 250 may be provided on the fourth planarization layer 119 so as to overlap the light-emitting diode LED provided in each of the subpixels SP1, SP2 and SP3, and may have a convex shape toward a second substrate 290. The lens 250 may be disposed to correspond to the light-emitting diode LED one to one. In addition, the lens 250 may be disposed as a plurality of lenses 250.

The lens 250 may condense light generated from the light-emitting diode LED overlapped with the lens 250 and send the condensed light to the outside. In more detail, a portion of the light generated from the light-emitting diode LED may enter the lens 250 by transmitting the fourth planarization layer 119. In general, when a distance between a light source and a lens is short, the amount of light from the light source toward a front surface, that is, a direction in which a viewing angle is 0°, is reduced. The fourth planarization layer 119 may increase the amount of the light emitted to the front surface by passing through the lens 250 with a distance between the lens 250 and the light-emitting diode LED that is a light source.

The lens 250 may be made of an organic material having a refractive index greater than that of the fourth planarization layer 119. That is, the lens 250 may have a second refractive index greater than the first refractive index. For example, the second refractive index may be greater than 1.5, preferably may be 1.64, but is not limited thereto. The lens 250 may have a refractive index different from that of the fourth planarization layer 119, but is not limited thereto. The lens 250 may have the same refractive index as that of the fourth planarization layer 119.

A low refractive planarization layer (also referred to as a low refractive layer) 260 may be provided on the lens 250 to cover the lens 250. The low refractive planarization layer 260 may planarize a step difference generated by the lens 250. The low refractive planarization layer 260 may be made of an organic material having a refractive index lower than that of the lens 250. The low refractive planarization layer 260 may have a third refractive index smaller than the second refractive index. For example, the third refractive index may be 1.4 to 1.5, preferably 1.44, but is not limited thereto.

In the light-emitting diode display apparatus according to one embodiment of the present disclosure, as the low refractive planarization layer 260 has a third refractive index smaller than the second refractive index of the lens 250, the light for transmitting the lens 250 may be refracted toward a front surface from the convex surface of the lens 250, that is, in a direction in which the viewing angle is 0°. The light-emitting diode display apparatus according to one embodiment of the present disclosure may further increase a light condensing effect of the lens 250 by forming the low refractive planarization layer 260 made of an organic material having a refractive index smaller than that of the lens 250. Therefore, the light-emitting diode display apparatus according to one embodiment of the present disclosure may maximize luminance on the front surface.

As a difference between the second refractive index and the third refractive index is increased, the amount of light directed toward a direction, in which the viewing angle is 0°, by passing through the lens 250 may be increased.

An upper organic layer 270 may be provided on the low refractive planarization layer 260. The upper organic layer 270 may be formed of an organic layer such as photopolymerization acrylate, acryl resin, epoxy resin, phenolic resin, polyamide resin and polyimide resin. The low refractive planarization layer 260 may be made of a transparent material so that it may be transmitted well by the light generated from the light-emitting diode LED.

With reference to FIGS. 3 and 4A, a scattering pattern 280 may be provided on the same layer as the upper organic layer 270. The scattering pattern 280 does not overlap the lens 250. A portion of the scattering pattern 280 may overlap the bank BM. According to one embodiment of the present disclosure, the scattering pattern 280 may be in the shape of a circular ring or a donut. The scattering pattern 280 may be disposed such that a part of light generated from the light-emitting diode LED which is not emitted toward a front surface of the light-emitting diode display apparatus passes through the scattering pattern 280. When there is no scattering pattern 280, light, which does not pass through the lens 250, among the light generated from the light-emitting diode LED is not emitted toward the front surface, that is, in a direction in which the viewing angle is 0°, so that the light is lost due to internal total reflection, whereby front luminance of the display apparatus may be lowered. However, when there is the scattering pattern 280, light, which does not pass through the lens 250, passes through the scattering pattern 280, and a direction of some light is changed to the front surface so that front luminance and the total extracted light amount of the display apparatus are increased.

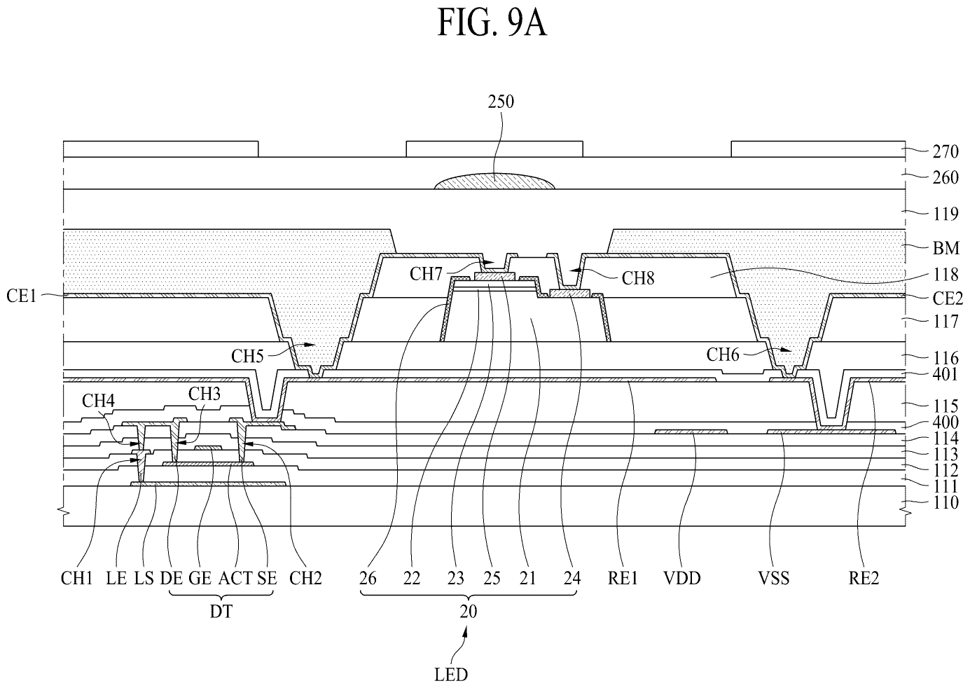

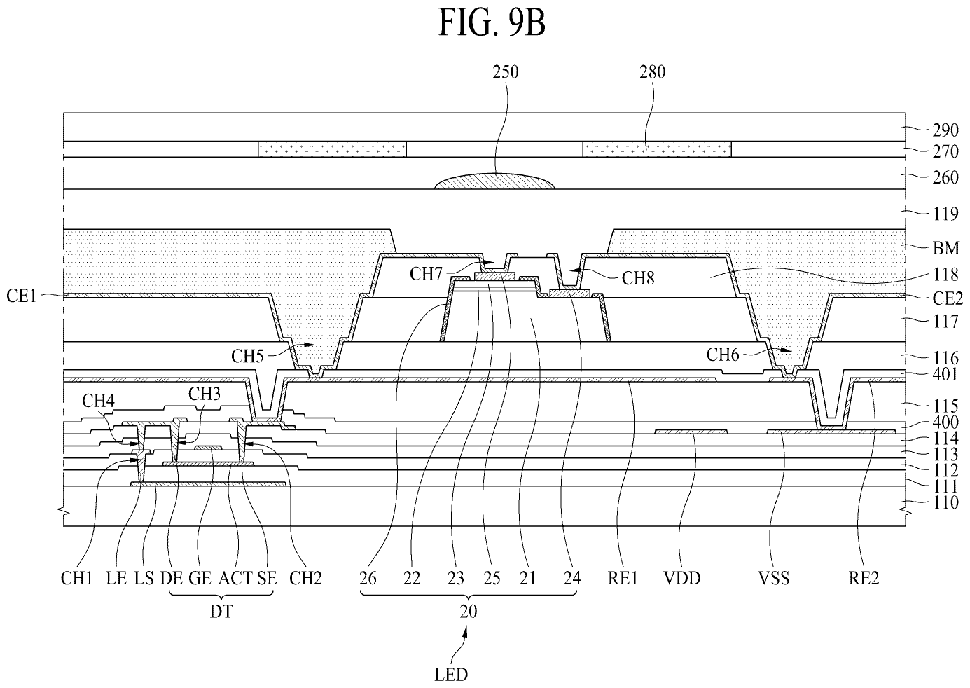

With reference to FIGS. 9A and 9B, after a partial area of the upper organic layer 270 is removed through a photolithography process, the scattering pattern 280 may be formed by inkjet coating for an organic layer including scattering particles in the partial area. In this case, the upper organic layer 270 serves as a dam so that the organic layer including the scattering particles may be prevented from being formed in another area other than an area in which the scattering pattern 280 is to be formed.

The second substrate 290 may be disposed to face the first substrate 100, thereby protecting a pixel array provided on the first substrate 100. The second substrate 290 may be defined as an opposite substrate, an encapsulation substrate, a color filter array substrate or an anti-scattering film. The second substrate 290 may be made of a transparent glass material, a transparent plastic material or a film material, but is not limited thereto.

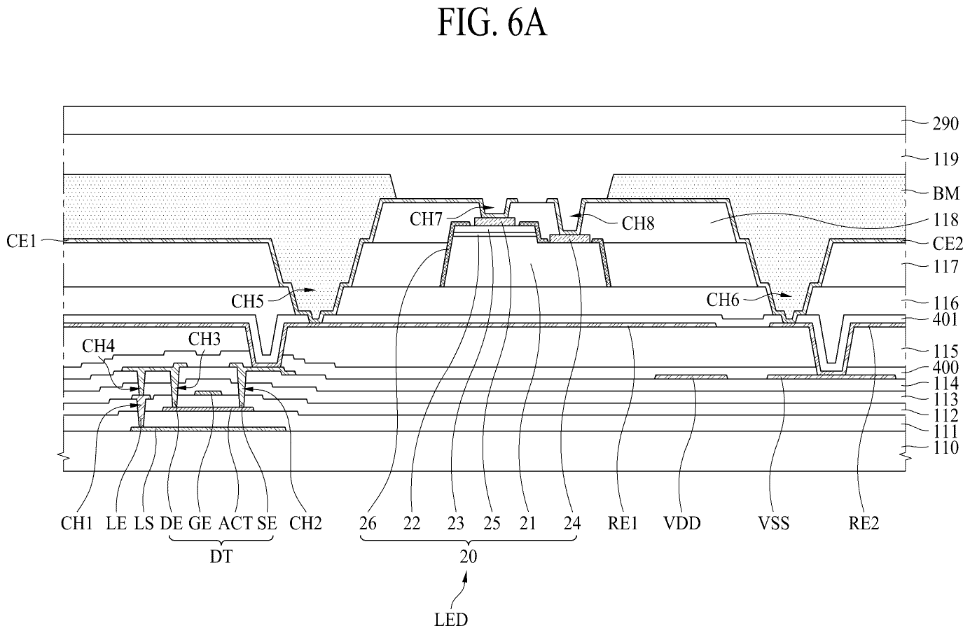

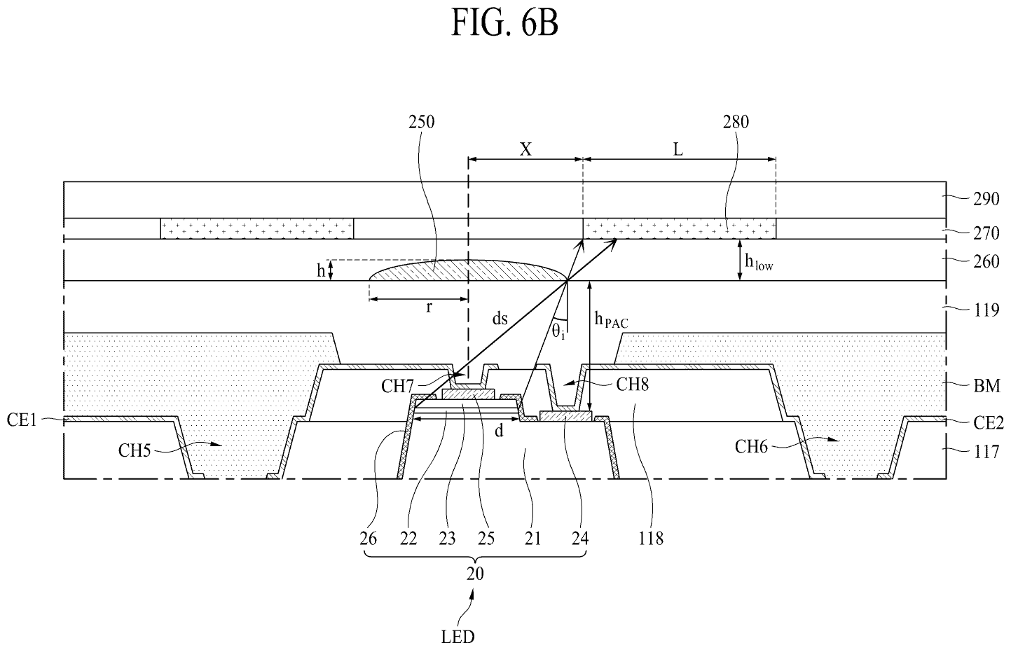

FIG. 6B is a partial cross-sectional view illustrating a position relationship between elements in a display apparatus according to one embodiment of the present disclosure. The light-emitting diode LED shown in FIG. 6B is the first light-emitting diode 120, but the same position relationship may be applied to the second light-emitting diode 130 and the third light-emitting diode 140.

With reference to FIG. 6B, ‘d’ is a length of the light-emitting layer 22, ‘r’ is a radius of the lens 250, how is a thickness of the low refractive planarization layer 260, ‘X’ is a horizontal distance from the center of the light-emitting layer 22 to an inner side of the scattering pattern 280, hPAC is a distance from a top surface of the n-type electrode 24 to a top surface of the fourth planarization layer 119, ‘h’ is a thickness of the lens 250, and θi may be an angle between a straight line perpendicular to the second substrate 290 and a straight line reaching the upper organic layer 270 by passing through an end of the lens 250 at a shortest distance after starting from an end of the light-emitting layer 22, which is closer to the n-type electrode 24.

The scattering pattern 280 may be positioned on an area through which the light, which does not pass through the lens 250, among the light generated from the light-emitting layer 22 passes. A distance from a point where light having the angle θi generated in the light-emitting layer 22 reaches the upper organic layer 270 to the center of the light-emitting layer 22 may be referred to as X. Therefore, the scattering pattern 280 may start from a place horizontally spaced apart from the center of the light-emitting layer 22 as much as X. The position of the scattering pattern 280 may be described by Equation 1 below.

$$X = \frac{{h}_{low} \times ( r - \frac{d}{2} )}{{h}_{PAC}} + \frac{d}{2} \qquad [ Equation 1 ]$$

That is, the scattering pattern 280 may be spaced apart from the center of the light-emitting layer 22 as much as minimum X in the horizontal direction.

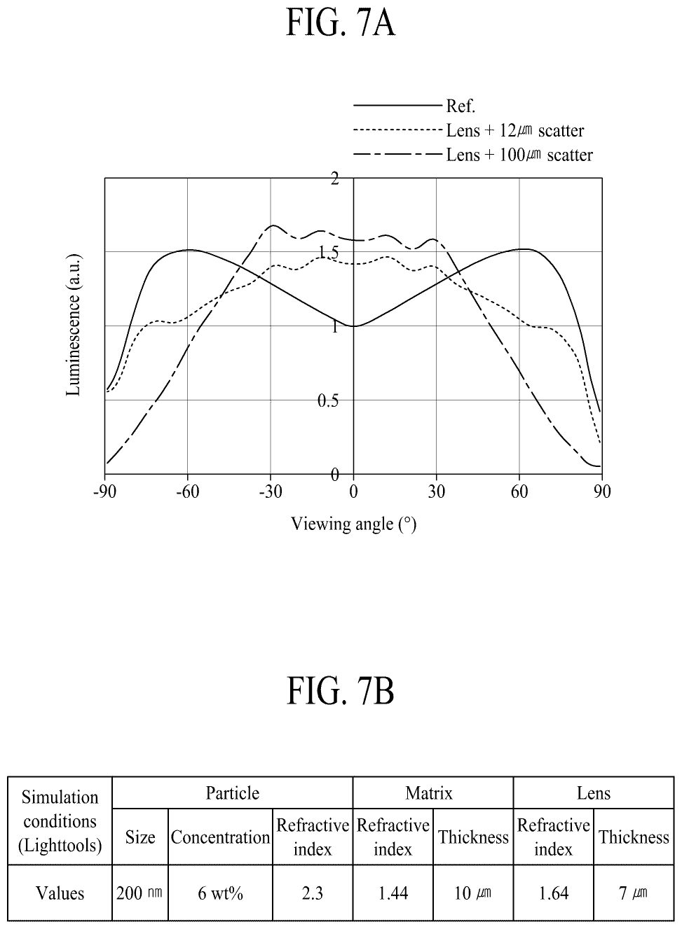

FIG. 7A is a graph illustrating simulation results for a luminance change per viewing angle of a light-emitting diode display apparatus to which the lens 250 and the scattering pattern 280, which are shown in FIG. 6B, are applied. FIG. 7B is a table showing input conditions to derive the simulation results shown in FIG. 7A.

With reference to FIG. 7A, Ref. is a luminance graph of the display apparatus according to the comparative embodiment shown in FIG. 6A, and the other two graphs are luminance graphs of the display apparatus according to the embodiment shown in FIG. 6B.

With reference to FIG. 7B, simulation conditions and results thereof are as follows. Scattering particles included in the scattering pattern 280 have a diameter of 200 nm, a mass fraction (i.e., concentration) of 6 wt % and a refractive index of 2.3. A matrix into which the scattering particles are injected has a refractive index of 1.44 and a thickness of 10 μm. The high refractive lens 250 has a refractive index of 1.64 and a thickness ‘h’ of 7 μm. In the conditions of FIG. 7B, for example, when the mass fraction of the scattering particles is reduced, the degree of scattering of light passing through the scattering pattern 280 is reduced, and when the thickness of the scattering pattern 280 is increased, the degree of scattering of light passing through the scattering pattern 280 is increased. That is, in addition to the conditions shown in FIG. 7B, the size of the scattering particles and the thickness of the scattering pattern 280 may be adjusted so that front luminance and the total extracted amount of light may be increased as shown in the simulation results shown in FIG. 7A.

In the light-emitting diode display apparatus according to FIG. 6A, the light generated from the light-emitting diode LED may be emitted to the outside through the second substrate 290 as it is without being reflected or refracted. Therefore, as shown in the Ref. graph of FIG. 7A, the light-emitting diode display apparatus according to FIG. 6A may have a luminance distribution of an ‘M’ shape having maximum luminance at a viewing angle greater than 0°, similarly to luminance distribution per viewing angle of the light generated from the light-emitting diode LED.

For example, when the light generated from the light-emitting diode LED has maximum luminance at a viewing angle of 60°, the light-emitting diode display apparatus according to FIG. 6A may have maximum luminance at a viewing angle of 60°, and may have an inefficient luminance distribution due to low luminance on the front surface of 0°.

The light-emitting diode display apparatus according to FIG. 6B may further include a low refractive planarization layer 260, a lens 250, an upper organic layer 270 and a scattering pattern 280, which are provided on the light-emitting diode LED, in comparison with the light-emitting diode display apparatus according to FIG. 6A.

As described above, light, which passes through the lens 250, among the light generated from the light-emitting diode LED of the light-emitting diode display apparatus according to FIG. 6B may change a path in a direction in which the viewing angle is 0°. In addition, light that does not pass through the lens 250 may enter the scattering pattern 280 so as to collide with the scattering particles, and a light-emitting direction of a portion of the light is changed toward the front surface (viewing angle of 0°) so that luminance on the front surface (viewing angle of 0°) and the total extracted amount of light of the display apparatus are increased.

Accordingly, in the light-emitting diode display apparatus according to FIG. 6B, luminance of light in the vicinity of the viewing angle of 60° is reduced as compared with the light-emitting diode display apparatus according to FIG. 6A, whereas luminance of the light in the vicinity of the viewing angle of 0° may be increased.

With reference to FIGS. 6B and 7A, a width of the scattering pattern 280 may be referred to as L. With reference to FIG. 3, a width between an inner ring and an outer ring of the scattering pattern 280 is defined as L. In this case, a size of L may be adjusted to make sure of desired front luminance. When luminance on the front surface of the light-emitting diode display apparatus according to FIG. 6A is 100% and L is 12 μm, it is noted that luminance on the front surface of the light-emitting diode display apparatus according to FIG. 6B is 140% increased as much as 40% as compared with the light-emitting diode display apparatus according to FIG. 6A. In addition, when L is 100 μm, it is noted that luminance on the front surface of the light-emitting diode display apparatus according to FIG. 6B is 160% increased as much as 60% as compared with the light-emitting diode display apparatus according to FIG. 6A. That is, as L is increased, an area of the scattering pattern 280 is increased, and therefore, the amount of light passing through the scattering pattern 280 is increased so that front luminance is increased.

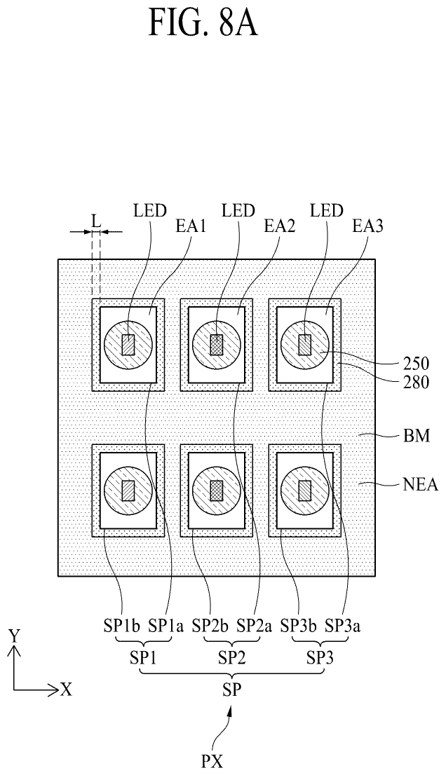

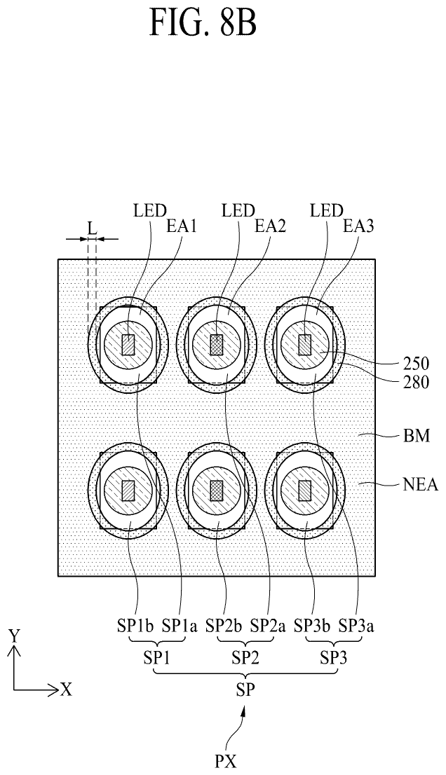

FIGS. 8A and 8B are enlarged plan views illustrating a display apparatus according to another embodiment of the present disclosure. The light-emitting diode display apparatus according to FIGS. 8A and 8B may have the same structure as that of the light-emitting diode shown in FIGS. 4A and 6B except for the shape of the scattering pattern 280. In the light-emitting diode display apparatus according to FIG. 8A, the scattering pattern 280 is in the shape of a square ring, and a portion of the scattering pattern 280 may overlap the bank BM. In the light-emitting diode display apparatus according to FIG. 8B, the scattering pattern 280 may be in the shape of an oval ring, and a portion of the scattering pattern 280 may overlap the bank BM.

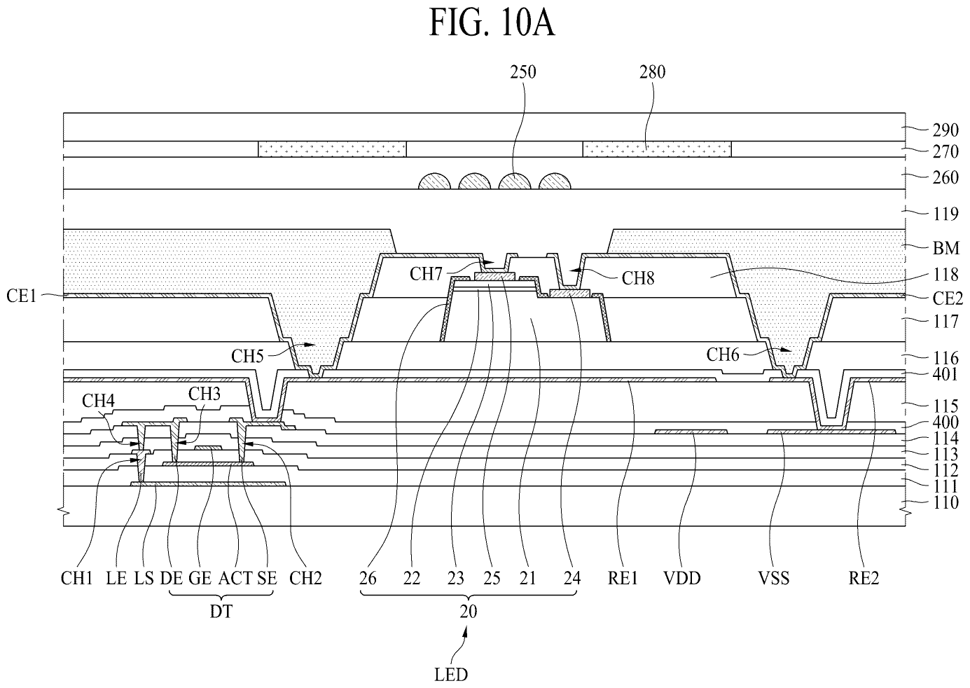

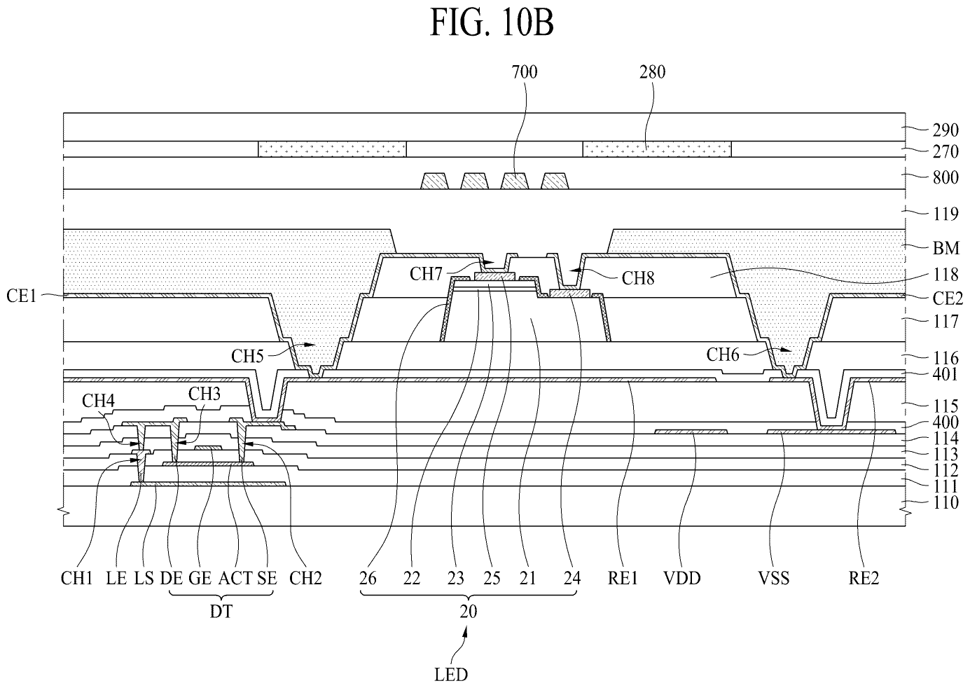

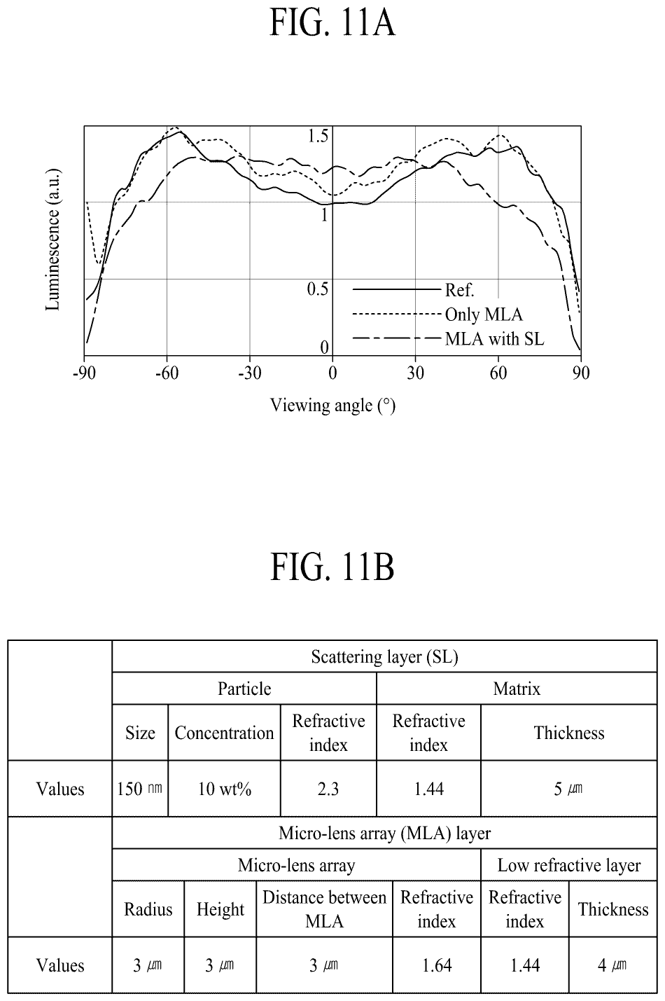

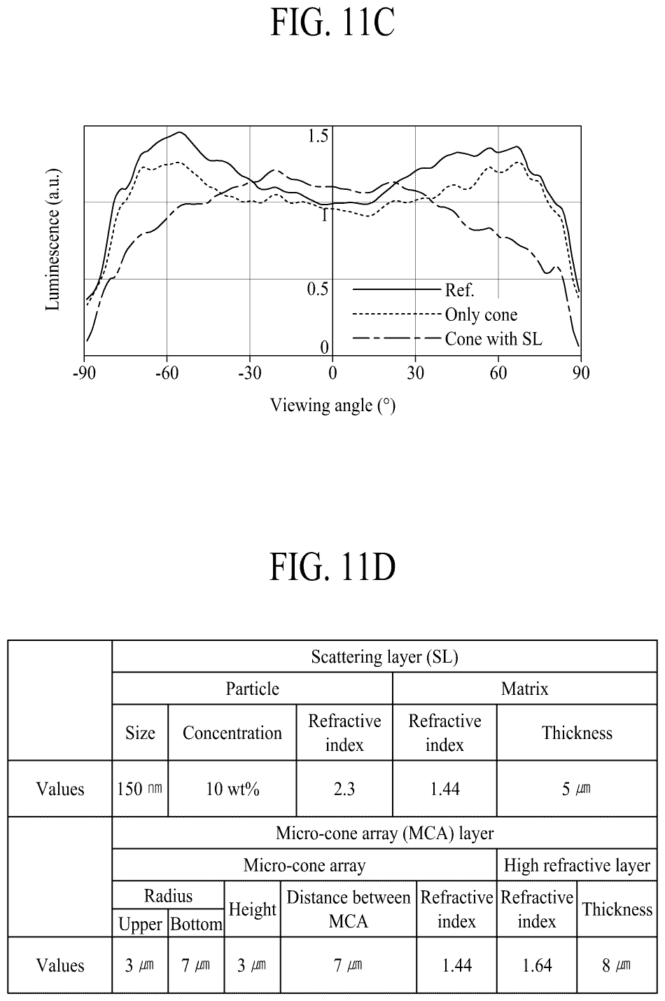

FIGS. 10A and 10B are partial cross-sectional views illustrating a display apparatus according to another embodiment of the present disclosure. In detail, FIGS. 10A and 10B illustrate another embodiment of the present disclosure in which the shape and number of lenses 250 are modified. In addition, FIGS. 11A to 11D are graphs and tables illustrating a luminance change of a display apparatus according to another embodiment of the present disclosure. In detail, FIGS. 11A and 11B are graphs and tables illustrating the display apparatus disclosed in FIG. 10A, and FIGS. 11C and 11D are graphs and tables illustrating the display apparatus disclosed in FIG. 10B.

Another embodiment of the present disclosure will be described with reference to FIGS. 10A to 11B. In the light-emitting diode display apparatus of the present disclosure, the remaining elements except for the shape and number of the lens 250 may have the same structure as that of the light-emitting diode shown in FIGS. 4A and 6B.

In the light-emitting diode display apparatus according to FIG. 10A, a plurality of high refractive lenses may be provided, and may have a hemisphere shape. A size of each of the high refractive lenses shown in FIG. 10A may be smaller than that of the high refractive lens shown in FIG. 4A.

With reference to FIGS. 10A, 11A and 11B, simulation results for the display apparatus corresponding to FIG. 10A and conditions thereof are as follows. Scattering particles included in the scattering patterns 280 (also referred to as a scattering layer (SL)) have a diameter of 150 nm, a mass fraction (i.e., concentration) of 10 wt % and a refractive index of 2.3. The matrix into which the scattering particles are injected has a refractive index of 1.44 and a thickness of 5 μm. In the plurality of lenses 250 (also referred to as a micro-lens array (MLA)), 16 lenses 250 are disposed inside an area having a width of 36 μm and a length of 36 μm so that a distance between the adjacent lenses 250 reaches 3 μm. The lens 250 has a radius of 3 μm, a thickness ‘h’ of 3 μm, and a refractive index of 1.64. The low refractive planarization layer (i.e., the low refractive layer) 260 has a refractive index of 1.44 and a thickness h_{low} of 4 μm.

FIG. 11A is a graph illustrating luminance simulation results for each condition of the light-emitting diode display apparatus according to FIG. 10A. With reference to FIG. 11A, in the light-emitting diode display apparatus according to FIG. 10A, (i) in Ref. condition that there are no low refractive planarization layer 260, lens 250, upper organic layer 270 and scattering pattern 280, luminance of the light-emitting diode display apparatus is 1 in the case that the viewing angle of the Ref. condition is 0°, (ii) in Only MLA condition that there are the low refractive planarization layer 260 and the lens 250 but are no upper organic layer 270 and scattering pattern 280, luminance may be more increased as much as 8% than that of the Ref. condition, and (iii) in an MLA with SL condition that there are all of the low refractive index planarization layer 260, the lens 250, the upper organic layer 270 and the scattering pattern 280, luminance may be more increased as much as 25% than that of the Ref. condition.

The light-emitting diode display apparatus according to FIG. 10B includes a reflective structure 700 and a high refractive planarization layer 800, and other elements are the same as those of the light-emitting diode display apparatus according to FIG. 10A, and thus their description will be omitted. In the light-emitting diode display apparatus according to FIG. 10B, the high refractive planarization layer 800 may be disposed on the fourth planarization layer 119. The reflective structure 700 is disposed in an area that does not overlap the scattering pattern 280 on the high refractive planarization layer 800. The number of the reflective structures 700 is plural, and the shape of the reflective structure 700 may be a cylinder in which an area of a lower surface is larger than that of an upper surface, i.e., a truncated cone. A size of the reflective structure 700 shown in FIG. 10B may be smaller than that of the lens 250 shown in FIG. 4A. Also, in the light-emitting diode display apparatus according to FIG. 10B, the high refractive planarization layer 800 may have a refractive index equal to or greater than that of the reflective structure 700.

With reference to FIGS. 10B, 11C and 11D, simulation results for the display apparatus corresponding to FIG. 10B and conditions thereof are as follows. Scattering particles included in the scattering pattern 280 have a diameter of 150 nm, a mass fraction of 10 wt %, and a refractive index of 2.3. The matrix into which the scattering particles are injected has a refractive index of 1.44 and a thickness of 5 μm. In the reflective structure (also referred to as a micro-cone array (MCA) 700, 16 reflective structures 700 are disposed inside an area having a width of 36 μm and a length of 36 μm so that a distance between the adjacent reflective structures 700 reaches 7 μm. The reflective structure 700 has an upper radius of 3 μm, a lower radius of 7 μm, a thickness of 3 μm, and a refractive index of 1.44. The high refractive planarization layer (also referred to as a high refractive layer) 800 has a refractive index of 1.64 and a thickness of 8 μm.

FIG. 11C is a graph illustrating luminance simulation results for each condition of the light-emitting diode display apparatus according to FIG. 10B. With reference to FIG. 11C, in the light-emitting diode display apparatus according to FIG. 10B, (i) in Ref. condition that there are no high refractive planarization layer 800, reflective structure 700, upper organic layer 270 and scattering pattern 280, luminance of the light-emitting diode display apparatus is 1 in the case that the viewing angle of the Ref. condition is 0°, (ii) in Only cone condition that there are the high refractive planarization layer 800 and the reflective structure 799 but are no upper organic layer 270 and scattering pattern 280, luminance may be reduced as much as 3% than that of the Ref. condition, and (iii) in a Cone with SL condition that there are all of the high refractive index planarization layer 800, the reflective structure 700, the upper organic layer 270 and the scattering pattern 280, luminance may be more increased as much as 20% than that of the Ref. condition.

The light-emitting diode display apparatus according to the embodiment of the present disclosure may be described as follows.

The light-emitting diode display apparatus according to the embodiment of the present disclosure includes a substrate, a light-emitting diode provided on the substrate, and a scattering pattern provided on the light emitting diode, wherein the scattering pattern is disposed such that a part of light generated from the light-emitting diode which is not emitted toward a front surface of the light-emitting diode display apparatus passes through the scattering pattern and does not overlap the light-emitting.

The light-emitting diode display apparatus according to the embodiment of the present disclosure may further comprises: at least one lens disposed on the light-emitting diode, having a first refractive index; and a planarization layer disposed on the at least one lens, having a second refractive index smaller than the first refractive index, wherein the scattering pattern does not overlap the at least one lens.

The light-emitting diode display apparatus according to the embodiment of the present disclosure may further comprises: a reflective structure disposed on the light-emitting diode and having a third refractive index; and a planarization layer disposed on the reflective structure and having a fourth refractive index equal to or greater than the third refractive index, wherein the scattering pattern does not overlap the reflective structure.

The light-emitting diode display apparatus according to the embodiment of the present disclosure may further comprises an organic layer disposed on the light-emitting diode, wherein the scattering pattern is provided in a partial area of the organic layer that does not overlap the light-emitting diode.

In the light-emitting diode display apparatus according to the embodiment of the present disclosure, the at least one lens may be disposed to overlap the light-emitting diode.

In the light-emitting diode display apparatus according to the embodiment of the present disclosure, the scattering pattern may have one of a circular ring shape, an oval ring shape, and a rectangular ring shape.

The light-emitting diode display apparatus according to the embodiment of the present disclosure may further include a bank formed on the substrate, having an opening area, and light generated from the light-emitting diode may be emitted through the opening area, and the at least one lens is disposed in the opening area.

The light-emitting diode display apparatus according to the embodiment of the present disclosure may further comprises a bank formed on the substrate, having an opening area, wherein light generated from the light-emitting diode is emitted through the opening area, and the reflective structure is disposed in the opening area.

In the light-emitting diode display apparatus according to the embodiment of the present disclosure, the substrate may further include a plurality of pixel areas, each of the plurality of pixel areas may include a gate line and a data line, and the light-emitting diode may include at least one light-emitting diode disposed in the plurality of pixel areas.

In the light-emitting diode display apparatus according to the embodiment of the present disclosure, the light-emitting diode may include a first semiconductor layer, an active layer disposed on the first semiconductor layer, a second semiconductor layer disposed on the active layer, a first electrode disposed on the second semiconductor layer, and a second electrode disposed on the first semiconductor layer.

In the light-emitting diode display apparatus according to the embodiment of the present disclosure, the at least one lens may include a plurality of lenses.

In the light-emitting diode display apparatus according to the embodiment of the present disclosure, the light-emitting diode may include an n-type semiconductor layer, an active layer and a p-type semiconductor layer, and the at least one lens may overlap the light-emitting layer.

In the light-emitting diode display apparatus according to the embodiment of the present disclosure, the light-emitting diode may include an n-type semiconductor layer, an active layer and a p-type semiconductor layer, and the reflective structure overlaps the light-emitting layer.

In the light-emitting diode display apparatus according to the embodiment of the present disclosure, the bank may include a light absorbing material.

In the light-emitting diode display apparatus according to the embodiment of the present disclosure, a partial area of the scattering pattern may overlap the bank.

The light-emitting diode display apparatus according to the embodiment of the present disclosure may further include a driving transistor disposed between the substrate and the light-emitting diode, a first connection electrode disposed on the light-emitting diode, electrically connecting the driving transistor with the first electrode, and a second connection electrode disposed on the light-emitting diode and electrically connected to the second electrode.

In the light-emitting diode display apparatus according to the embodiment of the present disclosure, the first electrode may be disposed at the center of the light-emitting diode, and the first electrode may be disposed between the second electrodes based on one direction.

In the light-emitting diode display apparatus according to the embodiment of the present disclosure, a further planarization layer may be disposed between the at least one lens and the light-emitting diode so as to provide a distance between the at least one lens and the light-emitting diode.

In the light-emitting diode display apparatus according to the embodiment of the present disclosure, the at least one lens may have a convex shape to condense light generated from the light-emitting diode.

In the light-emitting diode display apparatus according to the embodiment of the present disclosure, the reflective structure may be a cylinder in which an area of a lower surface is larger than that of an upper surface of the cylinder.

The light emitting diode display apparatus according to the embodiment of the present disclosure may include a substrate in which a plurality of pixels are disposed, first and second light-emitting diodes respectively disposed in two of the plurality of pixels on the substrate, a bank disposed in an area, which does not overlap the first and second light-emitting diodes, on the substrate, a lens or a reflective structure disposed to overlap each of the first and second light-emitting diodes, and a scattering pattern disposed on the lens or the reflective structure, wherein a partial area of the scattering pattern overlaps the bank.

In the light-emitting diode display apparatus according to the embodiment of the present disclosure, the first and second light-emitting diodes may have their respective shapes different from each other.

According to the present disclosure, the following advantageous effects may be obtained.

According to the present disclosure, as the scattering pattern is formed on the organic layer, the light, which has a large emission angle, among the light emitted from the light-emitting diode may be scattered. Therefore, front luminance and total extracted amount of light of the light-emitting diode display apparatus may be increased, and luminance distribution for each inefficient viewing angle may be improved.

According to the present disclosure, as the lens is disposed on the light-emitting diode, the light, which is directed toward a lateral direction of the display apparatus due to a small emission angle, among the light emitted from the light-emitting diode may be refracted in a front direction of the light-emitting diode display apparatus. Therefore, front luminance of the display apparatus may be further increased.

According to the present disclosure, as the reflective structure is disposed on the light-emitting diode, a part of the light emitted from the light-emitting diode may be reflected by the reflective structure and scattered by the scattering pattern as discussed above. Therefore, front luminance of the display apparatus may be further increased.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure includes the accompanying claims, and it is intended that all variations or modifications derived from the meaning, scope and equivalent concept of the claims fall within the scope of the present disclosure.

What is claimed is:

1. A light-emitting diode display apparatus, comprising:
a substrate;
a light-emitting diode provided on the substrate; and
a scattering pattern provided on the light emitting diode,
wherein the scattering pattern is disposed such that a part of light generated from the light-emitting diode, which is not emitted toward a front surface of the light-emitting diode display apparatus, passes through the scattering pattern and does not overlap the light-emitting diode.

2. The light-emitting diode display apparatus of claim 1, further comprising:
at least one lens disposed on the light-emitting diode, having a first refractive index; and
a planarization layer disposed on the at least one lens, having a second refractive index smaller than the first refractive index,
wherein the scattering pattern does not overlap the at least one lens.

3. The light-emitting diode display apparatus of claim 1, further comprising:
a reflective structure disposed on the light-emitting diode and having a third refractive index; and
a planarization layer disposed on the reflective structure and having a fourth refractive index equal to or greater than the third refractive index,
wherein the scattering pattern does not overlap the reflective structure.

4. The light-emitting diode display apparatus of claim 2, further comprising an organic layer disposed on the light-emitting diode,
wherein the scattering pattern is provided in a partial area of the organic layer that does not overlap the light-emitting diode.

5. The light-emitting diode display apparatus of claim 2, wherein the at least one lens is disposed to overlap the light-emitting diode.

6. The light-emitting diode display apparatus of claim 1, wherein the scattering pattern has one of a circular ring shape, an oval ring shape, and a rectangular ring shape.

7. The light-emitting diode display apparatus of claim 2, further comprising a bank formed on the substrate, having an opening area,
wherein light generated from the light-emitting diode is emitted through the opening area, and
wherein the at least one lens is disposed in the opening area.

8. The light-emitting diode display apparatus of claim 3, further comprising a bank formed on the substrate, having an opening area,
wherein light generated from the light-emitting diode is emitted through the opening area, and
wherein the reflective structure is disposed in the opening area.

9. The light-emitting diode display apparatus of claim 1, wherein:
the substrate further includes a plurality of pixel areas,
each of the plurality of pixel areas includes a gate line and a data line, and
the light-emitting diode includes at least one light-emitting diode disposed in the plurality of pixel areas.

10. The light-emitting diode display apparatus of claim 1, wherein the light-emitting diode includes:
a first semiconductor layer;
an active layer disposed on the first semiconductor layer;
a second semiconductor layer disposed on the active layer;
a first electrode disposed on the second semiconductor layer; and
a second electrode disposed on the first semiconductor layer.

11. The light-emitting diode display apparatus of claim 2, wherein the at least one lens includes a plurality of lenses.

12. The light-emitting diode display apparatus of claim 2, wherein:
the light-emitting diode includes an n-type semiconductor layer, an active layer and a p-type semiconductor layer, and
the at least one lens overlaps the light-emitting layer.

13. The light-emitting diode display apparatus of claim 3, wherein:
the light-emitting diode includes an n-type semiconductor layer, an active layer and a p-type semiconductor layer, and
the reflective structure overlaps the light-emitting layer.

14. The light-emitting diode display apparatus of claim 7, wherein the bank includes a light absorbing material.

15. The light-emitting diode display apparatus of claim 7, wherein a partial area of the scattering pattern overlaps the bank.

16. The light-emitting diode display apparatus of claim 10, further comprising:
a driving transistor disposed between the substrate and the light-emitting diode;
a first connection electrode disposed on the light-emitting diode, electrically connecting the driving transistor with the first electrode; and
a second connection electrode disposed on the light-emitting diode and electrically connected to the second electrode.

17. The light-emitting diode display apparatus of claim 10, wherein:
the first electrode is disposed at the center of the light-emitting diode, and
the first electrode is disposed between the second electrodes based on one direction.

18. The light-emitting diode display apparatus of claim 2, wherein a further planarization layer is disposed between the at least one lens and the light-emitting diode so as to provide a distance between the at least one lens and the light-emitting diode.

19. The light-emitting diode display apparatus of claim 2, wherein the at least one lens has a convex shape to condense light generated from the light-emitting diode.

20. The light-emitting diode display apparatus of claim 3, wherein the reflective structure is a cylinder in which an area of a lower surface is larger than an area of an upper surface of the cylinder.

21. A light-emitting diode display apparatus, comprising:
a substrate in which a plurality of pixels are disposed;
first and second light-emitting diodes respectively disposed in two of the plurality of pixels on the substrate;
a bank disposed in an area, which does not overlap the first and second light-emitting diodes, on the substrate;
a lens or a reflective structure disposed to overlap each of the first and second light-emitting diodes; and
a scattering pattern disposed on the lens or the reflective structure,
wherein a partial area of the scattering pattern overlaps the bank.

22. The light-emitting diode display apparatus of claim 21, wherein the first and second light-emitting diodes have their respective shapes different from each other.
